(19) United States
(12) Patent Application Publication
(10) Pub. No.: US 2025/0068087 A1
(43) Pub. Date: Feb. 27, 2025

(54) MIRROR FOLDED ILLUMINATION FOR COMPACT OPTICAL METROLOGY SYSTEM

(71) Applicant: Applied Materials, Inc., Santa Clara, CA (US)

(72) Inventors: Yangyang SUN, San Jose, CA (US); Jinxin FU, Fremont, CA (US); Sihui HE, Santa Clara, CA (US)

(21) Appl. No.: 18/803,041

(22) Filed: Aug. 13, 2024

Related U.S. Application Data
(60) Provisional application No. 63/578,392, filed on Aug. 24, 2023.

(51) Int. Cl. G03F 7/00

(52) U.S. Cl. CPC G03F 7/706849; G03F 7/706837; G03F 7/706851; G03F 7/70725

(57) ABSTRACT

Embodiments of the present disclosure generally relate to metrology systems and metrology methods to measure waveguides for image quality standards. In at least one embodiment, an optical device metrology system includes a stage, a body, and a light engine positioned within the body and mounted above the stage. The light engine includes, a light source, a fold mirror angled relative to the light source, the fold mirror is configured to turn a light beam toward the stage, one or more lenses or arrays positioned between the fold mirror and the stage, and a projection lens positioned between the one or more lenses or arrays and the stage. The system further includes, a first detector positioned within the body and mounted above the stage adjacent to the light engine configured to receive the projected light beam projected upwardly from the stage.

### CROSS-REFERENCE TO RELATED APPLICATIONS

This application claims benefit of U.S. Provisional patent application Ser. No. 63/578,392, filed Aug. 24, 2023, which is herein incorporated by reference in its entirety.

### BACKGROUND

### Field

Embodiments of the present disclosure generally relate to metrology of waveguides. More specifically, embodiments described herein provide for a metrology system and a method for metrology of waveguides.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment. Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

Accordingly what is needed in the art is a metrology system and a metrology method to measure waveguides for image quality standards.

### SUMMARY

Embodiments of the present disclosure generally relate to metrology systems and metrology methods to measure waveguides for image quality standards. More particularly, embodiments described herein provide compact metrology systems that utilize mirror folded illumination to measure a plurality of metrics.

In at least one embodiment, an optical device metrology system is provided. The metrology system includes a stage configured to move a tray along a stage path and a body having a first opening and a second opening to allow the stage to move through the first opening and the second opening. The system further includes, a light engine positioned within the body and mounted above the stage, where the light engine is configured to direct a light beam toward the stage. The light engine includes, a light source, a fold mirror angled relative to the light source, the fold mirror is configured to turn the light beam toward the stage, one or more lenses or arrays positioned between the fold mirror and the stage along an optical path, and a projection lens positioned between the one or more lenses or arrays and the stage along an optical path. The system further includes, a first detector positioned within the body and mounted above the stage adjacent to the light engine configured to receive the projected light beam projected upwardly from the stage.

In at least one embodiment, an optical device metrology system is provided. The metrology system includes a stage configured to move a tray along a stage path and a body having a first opening and a second opening to allow the stage to move through the first opening and the second opening. The system further includes, a light engine positioned within the body and mounted above the stage, where the light engine is configured to direct a light beam toward the stage. The light engine includes, a light source, a first fold mirror angled relative to the light source, a second fold mirror opposite the first fold mirror, the second fold mirror is configured to turn the light beam toward the stage, one or more lenses or arrays positioned between the second fold mirror and the stage along an optical path, and a projection lens positioned between the one or more lenses or arrays and the stage along an optical path. The system further includes, a first detector positioned within the body and mounted above the stage adjacent to the light engine configured to receive the projected light beam projected upwardly from the stage.

In at least one embodiment, a method of analyzing optical devices is provided. The method includes, positioning an optical device within a measurement system and directing a light beam from a light engine toward the optical device. Directing the light beam includes, projecting the light beam from a light source of the light engine to a first fold mirror, turning the light beam toward the optical device, and projecting the light beam to one or more lenses or arrays and though a projection lens toward the optical device. The method further includes, capturing a plurality of first images of the projected light beam that projects from the optical device using a first detector and processing one or more of the plurality of first images to determine a plurality of first metrics of the optical device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a perspective, frontal view of a substrate according to embodiments described herein.

FIG. 1B is a perspective, frontal view of a waveguide according to embodiments described herein.

FIG. 2 is a schematic view of a metrology system according to embodiments described herein.

FIG. 3 is a schematic illustration of a light engine and reflection detector of a metrology system according to embodiments described herein.

FIG. 4 is a schematic illustration of a light engine of a metrology system according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to metrology systems and metrology methods to measure waveguides for image quality standards. More particularly, embodiments described herein provide compact metrology systems that utilize mirror folded illumination to measure a plurality of metrics. It has been discovered that the distance between a metrology systems light engine and reflection detector can be reduced by folding the illumination optics using one or more fold mirrors, resulting in the compact metrology systems described herein.

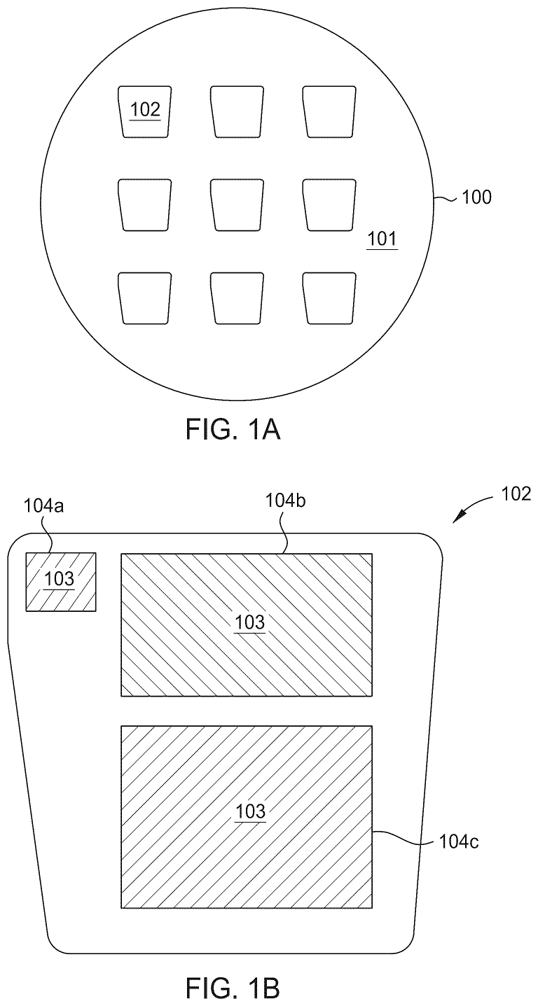

FIG. 1A is a perspective, frontal view of a substrate 100 according to embodiments described herein. The substrate includes a plurality of waveguides 102 disposed on a surface 101 of the substrate 100. The waveguides 102 are waveguide combiners utilized for virtual, augmented, or mixed reality.

FIG. 1B is a perspective, frontal view of a waveguide 102. It is to be understood that the waveguides 102 described herein are exemplary waveguides and the other waveguides may be used with or modified to accomplish aspects of the present disclosure. The waveguide 102 includes a plurality of waveguide structures 103 disposed on a surface 101 of a substrate 100. The waveguide structures 103 may be nanostructures having sub-micron dimensions, e.g., nano-sized dimensions. Regions of the waveguide structures 103 correspond to one or more gratings 104, such as a first grating 104a, a second grating 104b, and a third grating 104c. In one embodiment, which can be combined with other embodiments described herein, the waveguide 102 includes at least the first grating 104a corresponding to an input coupling grating and the third grating 104c corresponding to an output coupling grating. In another embodiment, which can be combined with other embodiments described herein, the waveguide 102 also includes the second grating 104b corresponding to an intermediate grating. The waveguide structures 103 may be angled or binary. The waveguide structures 103 may have other cross-sections including, but not limited to, circular, triangular, elliptical, regular polygonal, irregular polygonal, and/or irregular shaped cross-sections.

In operation, the first grating 104a receives incident beams of light having an intensity from a light engine. In one embodiment, which can be combined with other embodiments described herein, the light engine is a microdisplay. The incident beams are split by the waveguide structures 103 into beams that have all of the intensity of the incident beams in order to direct a virtual image to the intermediate grating (if utilized) or to the third grating 104c. The beams undergo total-internal-reflection (TIR) through the waveguide 102 until the beams come in contact with the waveguide structures 103 of the third grating 104c and are outcoupled to display the virtual image produced from the light engine.

To ensure that the waveguides 102 meet image quality standards, metrology metrics of the fabricated waveguides 102 must be obtained. The metrology metrics of each waveguide 102 are tested to ensure that pre-determined values are achieved. Embodiments of the measurement system 200 described herein provide for the ability to obtain multiple metrology metrics with increased throughput. The metrology metrics include one or more of an angular uniformity metric, a contrast metric, a efficiency metric, a color uniformity metric, a modulation transfer function (MTF) metric, a field of view (FOV) metric, a ghost image metric, and an eye box metric.

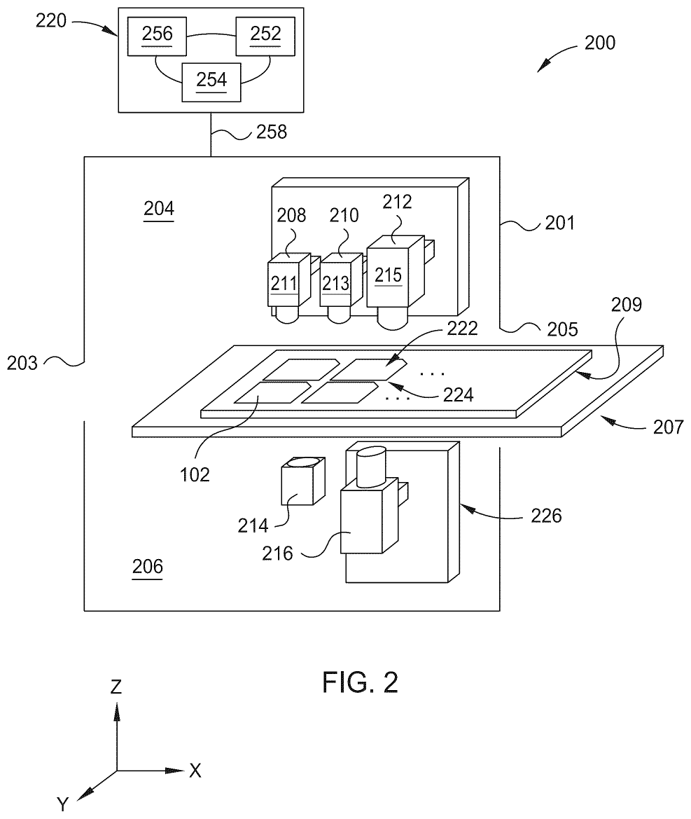

FIG. 2 is a schematic, cross-sectional view of a measurement system 200 according to embodiments described herein. The measurement system 200 includes a body 201 with a first opening 203 and a second opening 205 to allow a stage 207 to move therethrough. The stage 207 is operable to move in an X-direction, a Y-direction, and a Z-direction in the body 201 of the measurement system 200. The stage 207 includes a tray 209 operable to retain the waveguides 102 (as shown herein) or one or more substrates 101 with the waveguides 102 disposed thereon.

The measurement system 200 is operable to obtain one or more metrology metrics including one or more of the angular uniformity metric, the contrast metric, the efficiency metric, the color uniformity metric, the MTF metric, the FOV metric, the ghost image metric, or the eye box metric. The stage 207 and the tray 209 may be transparent such that the metrology metrics obtained by the measurement system 200 are not impacted by the translucence of the stage 207 or the tray 209. The measurement system 200 is in communication with a controller 220. The controller 220 is operable to facilitate operation of the measurement system 200.

The measurement system 200 includes an upper portion 204 oriented toward a top side 222 of the waveguides 102 and a lower portion 206 oriented toward a bottom side 224 of the waveguide 102. The upper portion 204 of the measurement system 200 includes an alignment camera 208, a light engine 210, and a reflection detector 212. The alignment camera 208 is operable to determine a position of the stage 207. The alignment camera 208 is also operable to determine a position of the waveguides 102 disposed on the stage 207. The alignment camera 208 includes an alignment camera body 211. The light engine 210 is operable to project light. For example, the light engine 210 is operable to illuminate a first grating 104a of the waveguides 102. The light engine 210 includes a light engine body 213. In one embodiment, which can be combined with other embodiments described herein, the light engine 210 projects a pattern to the first grating 104a. The reflection detector 212 detects outcoupled beams projected from a third grating 104c of the waveguides 102. The reflection detector 212 includes a reflection detector body 215. The outcoupled beams may be emitted from the top side 222 or the bottom side 224 of the waveguides 102. The outcoupled beams may correspond to the pattern from the light engine 210. One or more images of the pattern are detected by the reflection detector 212. The one or more images of the pattern may be processed with the controller 220 to extract each metrology metric.

The lower portion 206 of the measurement system 200 includes a code reader 214 and a transmission detector 216. The code reader 214 and the transmission detector are positioned opposite the alignment camera 208, the light engine 210, and the reflection detector 212 on the other side of the stage 207. The code reader 214 is operable to read a code of the waveguides 102, such as a quick response (QR) code or barcode of a waveguide 102. The code read by the code reader 214 may include identification information and/or instructions for obtaining the one or more metrology metrics of the waveguides 102. The transmission detector 216 detects outcoupled beams projected from the third grating 104c though the bottom side 224 of the waveguides 102. In one embodiment, which can be combined with other embodiments described herein, the transmission detector 216 is coupled to a transmission detector stage 226. The transmission detector stage 226 is operable to move the transmission detector 216 in an X-direction, a Y-direction, and a Z-direction. The transmission detector stage 226 is operable to adjust the position of the transmission detector 216 to enhance the detection of the outcoupled beams projected from the third grating 104c.

The controller 220 is coupled to the metrology system 200. The controller 220 includes a processor 252, a memory 254, and support circuits 256 that are coupled to one another. The controller 220 is electrically coupled to the metrology system 200 via a wire 258. The processor 252 may be one of any form of general purpose microprocessor, or a general purpose central processing unit (CPU), each of which can be used in an industrial setting, such as a programmable logic controller (PLC), supervisory control and data acquisition (SCADA) systems, general purpose graphics processing unit (GPU), or other suitable industrial controller. The memory 254 is non-transitory and may be one or more of readily available memory such as random access memory (RAM), read only memory (ROM), or any other form of digital storage, local or remote. The memory 254 contains instructions, that when executed by the processor 252, facilitates execution of the method. The instructions in the memory 254 are in the form of a program product such as a program that implements the method of the present disclosure. The program code of the program product may conform to any one of a number of different programming languages. Illustrative computer-readable storage media include, but are not limited to: (i) non-writable storage media (e.g., read-only memory devices within a computer such as CD-ROM disks readable by a CD-ROM drive, flash memory, ROM chips, or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are examples of the present disclosure.

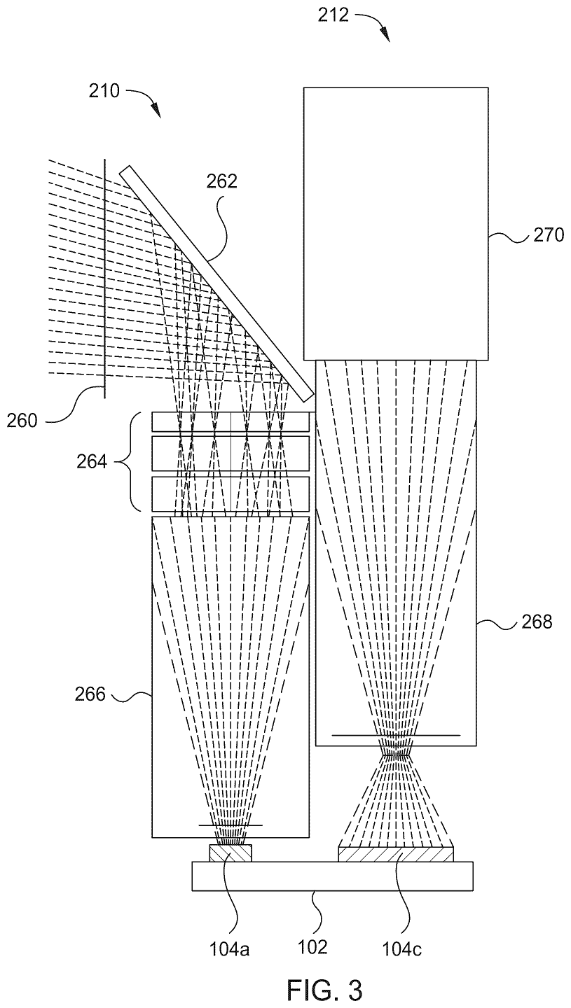

FIG. 3 is a schematic illustration of a light engine and reflection detector of a metrology system according to embodiments described herein.

In some embodiments, the light engine 210 includes a light source 260, such as an LED, which emits light to a fold mirror 262. The fold mirror 262 is angled relative to the light source 260. The fold mirror 262 is oriented to one side of the light engine 210 in the direction of the light source 260 at an angle of about 30 degrees to about 70 degrees. The angle of the fold mirror 262 allows the distance between the light engine 210 and the reflection detector 212 to be reduced to provide space for the reflection detector 212 to be positioned over the third grating 104c. The reduced distance also allows for a reduced footprint of the light engine 210 and the reflection detector 212. The distance between the light engine 210 and the reflection detector 212 may be about 10 millimeters (mm) to about 20 mm, such as about 15 mm. The distance from a first end of the light engine 210 away from the reflection detector 212 to a second end of the reflection detector 212 away from the light engine 210 may be about 30 mm to about 70 mm, such as about 50 mm.

The light is projected to a series 264 of lenses and/or arrays and though a projection lens 266 of the light engine 210. The reflection detector 212 captures the light reflected from the waveguide 102 to evaluate its performance based on the test pattern projected by the light engine 210. The reflection detector 212 includes a camera lens 268 and a camera 270.

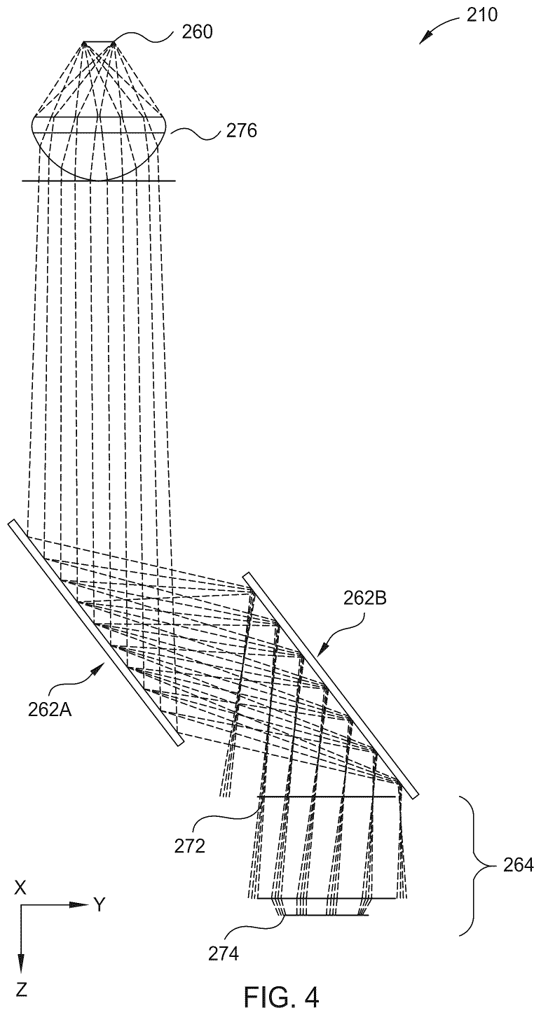

FIG. 4 is a schematic illustration of a light engine of a metrology system according to embodiments described herein.

In some embodiments, the light engine 210 includes a light source 260 positioned above one or more fold mirrors 262. The light emitted from light source 260 is projected through a lens 276 to a first fold mirror 262A. The first fold mirror 262A is angled relative to the light source 260 in such a way that the projected light is reflected to a second fold mirror 262B. The first fold mirror 262A and second fold mirror 262B are oriented to opposite sides of the light engine 210. The second fold mirror 262B is angled in such a way that the light reflected from the first fold mirror 262A is projected to a series 264 of lenses and/or arrays and though a projection lens 266 (not shown) of the light engine 210. The series 264 of lenses and/or arrays may include a diffuser 272 and a reticle 274.

The fold mirrors 262A and 262B fold the optical path of the light emitted by light source 260, allowing the distance between the light engine 210 and the reflection detector 212 to be reduced to provide space for the reflection detector 212 to be positioned over the third grating 104c. The reduced distance also allows for a reduced footprint of the light engine 210 and the reflection detector 212. The distance between the light engine 210 and the reflection detector 212 may be about 10 millimeters (mm) to about 20 mm, such as about 15 mm or less. The distance from a first end of the light engine 210 away from the reflection detector 212 to a second end of the reflection detector 212 away from the light engine 210 may be about 30 mm to about 70 mm, such as about 50 mm.

Overall, compact metrology systems and metrology methods that utilize mirror folded illumination to measure a plurality of metrics are shown and described herein. One or more fold mirrors are utilized to reduce the distance between a metrology system's light engine and reflection detector by folding the illumination optics, resulting in more compact metrology systems.

While the foregoing is directed to examples of the present disclosure, other and further examples of the disclosure may be devised without departing from the basic scope thereof, and the scope thereof is determined by the claims that follow.

What is claimed is:

1. An optical device metrology system, comprising:
a stage configured to move a tray along a stage path;
a body having a first opening and a second opening to allow the stage to move through the first opening and the second opening;
a light engine positioned within the body and mounted above the stage, wherein the light engine is configured to direct a light beam toward the stage, the light engine comprising;
a light source;
a fold mirror angled relative to the light source, the fold mirror is configured to turn the light beam toward the stage;
one or more lenses or arrays positioned between the fold mirror and the stage along an optical path; and
a projection lens positioned between the one or more lenses or arrays and the stage along an optical path; and
a first detector positioned within the body and mounted above the stage adjacent to the light engine configured to receive a projected light beam projected upwardly from the stage.

2. The optical device metrology system of claim 1, wherein the light source of the light engine is positioned on a side of the light engine opposite the first detector.

3. The optical device metrology system of claim 1, wherein the first detector comprises a camera and a camera lens positioned between the camera and the stage path.

4. The optical device metrology system of claim 1, wherein the fold mirror is angled at about 30 degrees to about 70 degrees.

5. The optical device metrology system of claim 1, wherein a distance between the light engine and the first detector is about 15 mm.

6. The optical device metrology system of claim 1, wherein a distance from a first end of the light engine away from the first detector to a second end of the first detector away from the light engine is about 50 mm.

7. The optical device metrology system of claim 1, further comprising a second detector positioned within the body and mounted below the stage path configured to receive a second projected light beam projected downwardly from the stage.

8. The optical device metrology system of claim 1, further comprising a controller in communication with the stage, the light engine, and the first detector, wherein the controller comprises instructions that, when executed, determine:
one or more metrics of an optical device, the one or more metrics including one or more of an angular uniformity metric, a contrast metric, an efficiency metric, a color uniformity metric, a modulation transfer function (MTF) metric, a field of view (FOV) metric, a ghost image metric, or an eye box metric.

9. An optical device metrology system, comprising:
a stage configured to move a tray along a stage path;
a body having a first opening and a second opening to allow the stage to move through the first opening and the second opening;
a light engine positioned within the body and mounted above the stage, wherein the light engine is configured to direct a light beam toward the stage, the light engine comprising:
a light source;
a first fold mirror angled relative to the light source;
a second fold mirror opposite the first fold mirror, the second fold mirror is configured to turn the light beam toward the stage;
one or more lenses or arrays positioned between the second fold mirror and the stage along an optical path; and
a projection lens positioned between the one or more lenses or arrays and the stage along an optical path; and
a first detector positioned within the body and mounted above the stage adjacent to the light engine configured to receive a projected light beam projected upwardly from the stage.

10. The optical device metrology system of claim 9, wherein the light source of the light engine is positioned above the first fold mirror.

11. The optical device metrology system of claim 9, wherein the first detector comprises a camera and a camera lens positioned between the camera and the stage.

12. The optical device metrology system of claim 9, wherein the one or more lenses or arrays comprise a diffuser and a reticle.

13. The optical device metrology system of claim 9, wherein a distance between the light engine and the first detector is about 15 mm.

14. The optical device metrology system of claim 9, wherein a distance from a first end of the light engine away from the first detector to a second end of the first detector away from the light engine is about 50 mm.

15. The optical device metrology system of claim 9, further comprising a second detector positioned within the body and mounted below the stage path configured to receive a second projected light beam projected downwardly from the stage path.

16. The optical device metrology system of claim 9, further comprising a controller in communication with the stage, the light engine, and the first detector, wherein the controller comprises instructions that, when executed, determine:
one or more metrics of an optical device, the one or more metrics including one or more of an angular uniformity metric, a contrast metric, an efficiency metric, a color uniformity metric, a modulation transfer function (MTF) metric, a field of view (FOV) metric, a ghost image metric, or an eye box metric.

17. A method of analyzing optical devices, comprising:
positioning an optical device within a measurement system;
directing a light beam from a light engine toward the optical device, wherein directing the light beam comprises;
projecting the light beam from a light source of the light engine to a first fold mirror;
turning the light beam toward the optical device; and
projecting the light beam to one or more lenses or arrays and though a projection lens toward the optical device;
capturing a plurality of first images of a projected light beam that projects from the optical device using a first detector; and
processing one or more of the plurality of first images to determine a plurality of first metrics of the optical device.

18. The method of claim 17, further comprising reflecting the light beam from the first fold mirror towards a second fold mirror.

19. The method of claim 17, wherein the plurality of first metrics include one or more of an angular uniformity metric, a contrast metric, an efficiency metric, a color uniformity metric, a modulation transfer function (MTF) metric, a field of view (FOV) metric, a ghost image metric, or an eye box metric.

20. The method of claim 17, wherein a distance between the light engine and the first detector is about 15 mm.
